(19) United States
(12) Patent Application Publication
(10) Pub. No.: US 2025/0294778 A1
(43) Pub. Date: Sep. 18, 2025

(54) MAGNETIC MEMORY DEVICE AND SEMICONDUCTOR DEVICE

(71) Applicant: Samsung Electronics Co., Ltd., Suwon-si (KR)

(72) Inventors: Minkwan Kim, Suwon-si (KR); Jonghyeon Kim, Suwon-si (KR); Kyungtae Nam, Suwon-si (KR); Kazutaka Yamane, Suwon-si (KR); Hyejin Eo, Suwon-si (KR); Joosung Oh, Suwon-si (KR); Dongkyu Lee, Suwon-si (KR); Pyunghwa Jang, Suwon-si (KR)

(21) Appl. No.: 19/023,718

(22) Filed: Jan. 16, 2025

(30) Foreign Application Priority Data
Mar. 13, 2024 (KR) 10-2024-0035432

(51) Int. Cl. H10B 61/00; H10N 50/10; H10N 50/85

(52) U.S. Cl. CPC H10B 61/10; H10N 50/10; H10N 50/85

(57) ABSTRACT

A magnetic memory device may include a lower electrode on a substrate, a magnetic tunnel junction pattern on the lower electrode, a capping pattern on the magnetic tunnel junction pattern, a stress inducing layer on the capping pattern and having a lattice constant less than a lattice constant of tantalum, a boron trap layer in contact with the stress inducing layer, and an upper electrode on the boron trap layer.

### CROSS-REFERENCE TO RELATED APPLICATIONS

This application is based on and claims priority under 35 U.S.C. § 119 to Korean Patent Application No. 10-2024-0035432, filed on Mar. 13, 2024, in the Korean Intellectual Property Office, the disclosure of which is incorporated by reference herein in its entirety.

### BACKGROUND OF THE INVENTION

The inventive concepts relate to a semiconductor device, and more particularly, to a magnetic memory device including a magnetic tunnel junction (MTJ) structure.

Magnetic memory devices may include a magnetic tunnel junction. The magnetic tunnel junction may include two magnetic bodies and an insulating film therebetween. The resistance value of the magnetic tunnel junction may vary depending on the magnetization directions of the two magnetic bodies. For example, when the magnetization directions of two magnetic bodies are antiparallel to each other, the magnetic tunnel junction may have a large resistance value, and when the magnetization directions of two magnetic bodies are parallel to each other, the magnetic tunnel junction may have a small resistance value. By using such a difference in the resistance value, data may be written/read. With the development of the electronics industry, magnetic memory devices having improved electrical properties and high reliability are helpful.

### SUMMARY OF THE INVENTION

The inventive concepts provide a magnetic memory device with improved electrical properties.

According to aspects of the inventive concepts, there is provided a magnetic memory device including a lower electrode on a substrate, a magnetic tunnel junction pattern on the lower electrode, a capping pattern on the magnetic tunnel junction pattern, a stress inducing layer on the capping pattern and having a lattice constant less than a lattice constant of tantalum, a boron trap layer in contact with the stress inducing layer, and an upper electrode on the boron trap layer.

According to aspects of the inventive concepts, there is provided a magnetic memory device including a lower electrode on a substrate, a magnetic tunnel junction pattern on the lower electrode, the magnetic tunnel junction pattern including a first magnetic pattern, a tunnel barrier pattern, and a second magnetic pattern, an upper electrode on the magnetic tunnel junction pattern, a capping pattern between the magnetic tunnel junction pattern and the upper electrode, a stress inducing layer between the capping pattern and the upper electrode, and a boron trap layer between the stress inducing layer and the upper electrode, the boron trap layer including boron. Each of the stress inducing layer and the second magnetic pattern may include boron.

According to aspects of the inventive concepts, there is provided a semiconductor device including a semiconductor substrate, a selection element on the semiconductor substrate, a lower interlayer insulating layer on the semiconductor substrate and the selection element, a conductive plug in the lower interlayer insulating layer and electrically connected to the selection element, an information storage structure on the conductive plug, and a bit line on the information storage structure. The information storage structure may include a lower electrode electrically connected to the conductive plug, a magnetic tunnel junction pattern on the lower electrode, the magnetic tunnel junction pattern including a first magnetic pattern, a tunnel barrier pattern, and a second magnetic pattern, a first capping pattern on an upper surface of the second magnetic pattern, the first capping pattern including a metal different from a metal included in the second magnetic pattern, a second capping pattern on the upper surface of the second magnetic pattern, the second capping pattern including a metal different from the metal included in the second magnetic pattern and the metal included in the first capping pattern, a stress inducing layer on an upper surface of the second capping pattern, the stress inducing layer having a lattice constant lower than a lattice constant of tantalum, a boron trap layer between the stress inducing layer and the bit line, and an upper electrode between the boron trap layer and the bit line.

### BRIEF DESCRIPTION OF THE DRAWINGS

Example embodiments of the inventive concepts will be more clearly understood from the following detailed description taken in conjunction with the accompanying drawings, in which:

FIG. 1 is a cross-sectional view for explaining a semiconductor device according to some embodiments;

FIG. 2 is a schematic view for explaining an electrical connection of a semiconductor device according to some embodiments;

FIG. 3 is a schematic view for explaining a magnetic tunnel junction pattern of an information storage structure according to some embodiments;

FIG. 4 is a schematic view for explaining a magnetic tunnel junction pattern of an information storage structure according to further embodiments;

FIG. 5A is a plan view of a semiconductor device according to some embodiments; and

FIG. 5B is a cross-sectional view of the semiconductor device taken along a line I-I′ of FIG. 5A.

### DETAILED DESCRIPTION

In the present disclosure, like reference numerals denote like components. A semiconductor device according to the inventive concepts is described hereinafter.

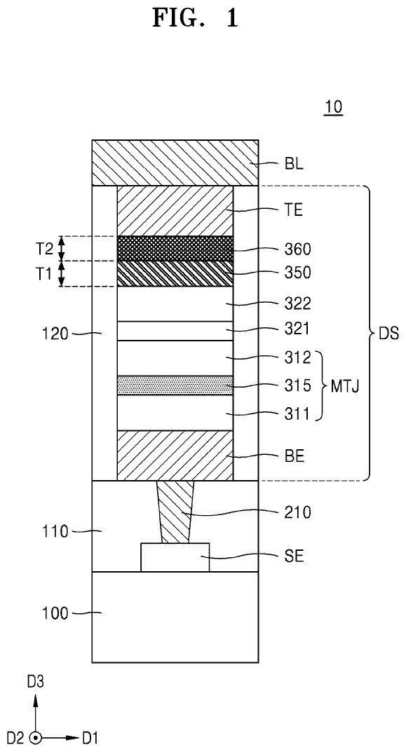

FIG. 1 is a cross-sectional view for explaining a semiconductor device according to some embodiments.

Referring to FIG. 1, the semiconductor device according to some embodiments may be a memory device such as a non-volatile memory device. A non-volatile memory device may include a variable resistance memory device. The semiconductor device of FIG. 1 may be a magnetic memory device 10. The magnetic memory device 10 may include a magnetoresistive random access memory (MRAM). As an example, the magnetic memory device 10 may include an embedded MRAM (eMRAM). As an example, the magnetic memory device 10 may include a perpendicular Magnetic Tunnel Junction-Spin Transfer Torque-MRAM (pMTJ-STT-MRAM).

The magnetic memory device 10 may include a substrate 100, a selection element SE, a lower interlayer insulating layer 110, a conductive plug 210, an information storage structure DS, an upper interlayer insulating layer 120, and a bit line BL.

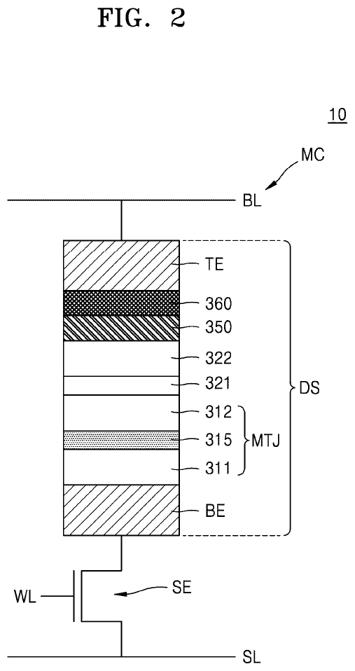

The substrate 100 may be provided. The substrate 100 may include a memory cell area, and a plurality of memory cells may be provided in the memory cell area. Each of the memory cells may be substantially the same as a memory cell MC to be described below with reference to FIG. 2. The substrate 100 may be a semiconductor substrate. For example, the substrate 100 may include silicon, germanium, and/or silicon-germanium. A first direction D1 may be parallel to a lower surface of the substrate 100. A second direction D2 may be parallel to the lower surface of the substrate 100 and may intersect with the first direction D1. For example, the second direction D2 may be perpendicular to the first direction D1. A third direction D3 may be substantially perpendicular to the lower surface of the substrate 100. The third direction D3 may be a vertical direction.

The selection element SE may be disposed on the substrate 100. The selection element SE may include a transistor. The transistor may include a planar transistor, a fin field effect transistor (FinFET), a recess channel array transistor (RCAT), a gate-all-around (GAA) type field effect transistor, a vertical transistor, a nanowire transistor, a multi-bridge channel (MBC) transistor, a three-dimensional transistor, a diode, or a combination thereof. The operation and function of the selection element SE is described below with reference to FIG. 2.

The lower interlayer insulating layer 110 is disposed on the substrate 100 to be on (e.g., to cover) the selection element SE. The lower interlayer insulating layer 110 may include a silicon-containing insulating material. The silicon-containing insulating material may include a silicon oxide, a silicon nitride, or a silicon oxynitride. The lower interlayer insulating layer 110 may be a single layer or a multilayer.

The conductive plug 210 may be provided in the lower interlayer insulating layer 110 and may be electrically connected to the selection element SE. The electrical connection to the selection element SE may mean an electrical connection to at least one of source/drains or a gate electrode of the selection element SE. As an example, the conductive plug 210 may be electrically connected to any one of the source/drains of the selection element SE. In the present disclosure, two components being electrically connected to each other may include a direct connection or an indirect connection via another component.

The information storage structure DS may be disposed on the conductive plug 210 and the lower interlayer insulating layer 110 so as to be electrically connected to the conductive plug 210. Accordingly, the information storage structure DS may be electrically connected to the selection element SE through the conductive plug 210.

The information storage structure DS may include a lower electrode BE, a magnetic tunnel junction (MTJ) pattern MTJ, a first capping pattern 321, a second capping pattern 322, a stress inducing layer 350, a boron trap layer 360, and an upper electrode TE. The lower electrode BE may be provided between the conductive plug 210 and the magnetic tunnel junction pattern MTJ. The lower electrode BE may include a conductive material, such as a metal material or a metal nitride. For example, the lower electrode BE may include tantalum (Ta), ruthenium (Ru), titanium (Ti), titanium nitride (TiN), tantalum nitride (TaN), tungsten (W), or a combination thereof. The lower electrode BE maybe a single layer or a multilayer.

The magnetic tunnel junction pattern MTJ may include a first magnetic pattern 311, a second magnetic pattern 312, and a tunnel barrier pattern 315. The first magnetic pattern 311, the tunnel barrier pattern 315, and the second magnetic pattern 312 may be stacked on the lower electrode BE. For example, the first magnetic pattern 311 may be disposed between the lower electrode BE and the second magnetic pattern 312. Any one of the first magnetic pattern 311 and the second magnetic pattern 312 may be a pinned layer, and the other one may be a free layer. For example, the first magnetic pattern 311 may be a pinned layer, and the second magnetic pattern 312 may be a free layer. In another example, the first magnetic pattern 311 may be a free layer, and the second magnetic pattern 312 may be a pinned layer. The pinned layer may have, under a typical usage environment, a fixed magnetization direction regardless of an external magnetic field. The magnetization direction of a free layer may be freely changed by an external magnetic field.

The first magnetic pattern 311 may include a ferromagnetic material. The ferromagnetic material may include at least one of cobalt (Co), nickel (Ni), or iron (Fe). The first magnetic pattern 311 may further include boron (B), but the present disclosure is not limited thereto. For example, the first magnetic pattern 311 may include cobalt iron (CoFe), cobalt boride (CoB), cobalt iron boride (CoFeB), cobalt nickel (CoNi), cobalt chromium (CoCr), cobalt platinum (CoPt), iron boride (FeB), cobalt iron aluminum (CeFeAl), or a combination thereof. The first magnetic pattern 311 may have a crystalline structure. The first magnetic pattern 311 may be a single layer or a multilayer.

The tunnel barrier pattern 315 may be disposed between the first magnetic pattern 311 and the second magnetic pattern 312. The tunnel barrier pattern 315 may include a dielectric material. The tunnel barrier pattern 315 may include, for example, at least one of magnesium oxide, titanium oxide, aluminum oxide, magnesium-zinc oxide, or magnesium-boron oxide.

The second magnetic pattern 312 may be disposed on the tunnel barrier pattern 315. The second magnetic pattern 312 may be spaced apart from the first magnetic pattern 311 by the tunnel barrier pattern 315. The second magnetic pattern 312 may include a ferromagnetic material and boron. The ferromagnetic material is the same as described above. For example, the second magnetic pattern 312 may include CoB, CoFeB, FeB, cobalt nickel boride (CoNiB), cobalt chromium boride (CoCrB), cobalt platinum boride (CoPtB), cobalt iron aluminum (CoFeAl), or a combination thereof. The second magnetic pattern 312 may have a crystalline structure. The second magnetic pattern 312 may include boron (B), and may have desired magnetic properties and crystalline structure. The second magnetic pattern 312 may be a single layer or a multilayer.

A capping pattern may be provided on the magnetic tunnel junction pattern MTJ to protect the magnetic tunnel junction pattern MTJ. The capping pattern may include the first capping pattern 321 and the second capping pattern 322. For example, the first and second capping patterns 321 and 322 may be provided between the magnetic tunnel junction pattern MTJ and the stress inducing layer 350. The first capping pattern 321 may be disposed on the second magnetic pattern 312. As an example, the first capping pattern 321 may be in contact with an upper surface of the second magnetic pattern 312. The first capping pattern 321 may include a first capping metal. The first capping metal may include metal, metal nitride, or metal oxide. For example, the first capping metal may include tantalum (Ta), tantalum oxide (Ta₂O₅), and/or tantalum nitride (TaN). In another example, the first capping metal may include aluminum nitride (AlN), zirconium nitride (ZrN), and/or niobium nitride (NbN). In some embodiments, the first capping pattern 321 may include a metal different from a metal included in the first magnetic pattern 311 and/or a metal included in the second magnetic pattern 312. The first capping pattern 321 may further include boron (B). In this case, the content (i.e., concentration) of boron in the first capping pattern 321 may be less than the content (i.e., concentration) of the first capping metal.

The second capping pattern 322 may be disposed on the first capping pattern 321. As an example, the second capping pattern 322 may be in contact with an upper surface of the first capping pattern 321, but the present disclosure is not limited thereto. The second capping pattern 322 may include a second capping metal. The second capping metal may be different from the first capping metal. In other words, the second capping pattern 322 may include a metal different from a metal included in the first capping pattern 321. The second capping metal may be different from the materials included in the first and second magnetic patterns 311 and 312. For example, the second capping metal may include ruthenium, ruthenium oxide, and/or a ruthenium alloy. In another example, the second capping metal may include Ru, Ta, Ti, TiN, TaN, W, and/or a combination thereof. The second capping pattern 322 may further include boron (B). In this case, the content (i.e., concentration) of boron in the second capping pattern 322 may be less than the content (i.e., concentration) of the second capping metal.

A stress inducing layer 350 may be disposed on the first and second capping patterns 321 and 322. The stress inducing layer 350 may be in contact with an upper surface of the second capping pattern 322, but the present disclosure is not limited thereto. The stress inducing layer 350 may have a lattice constant less than that of tantalum (Ta). For example, the lattice constant of the stress inducing layer 350 may be 3.3 angstroms (Å) or less. The stress inducing layer 350 may include a first metal material. The first metal material of the stress inducing layer 350 may be different from the second capping metal. In other words, the stress inducing layer 350 may include a metal different from a metal included in the second capping pattern 322. The first metal material may include, for example, molybdenum (Mo), tungsten (W), hafnium (Hf), and/or an alloy thereof. The stress inducing layer 350 may further include boron (B). The boron may be combined with the metal in the stress inducing layer 350, but the present disclosure is not limited thereto. The stress inducing layer 350 may include, for example, Mo, Mo boride (MoB), cobalt iron Mo (CoFeMo), CoFeMoB, and/or a combination thereof. The content (i.e., concentration) of boron in the stress inducing layer 350 may be less than the content (i.e., concentration) of the first metal material in the stress inducing layer 350. The stress inducing layer 350 may be formed by a deposition process.

The stress inducing layer 350 may apply stress such as compression stress to the magnetic tunnel junction pattern MTJ. For example, the stress inducing layer 350 may apply compression stress to the second magnetic pattern 312. Accordingly, the magnetic tunnel junction pattern MTJ may have interface perpendicular magnetic anisotropy (PMA) that is further improved by magnetostriction. The stress inducing layer 350 may prevent damage of the magnetic tunnel junction pattern MTJ. The damage of the magnetic tunnel junction pattern MTJ may include degradation at an interface between the tunnel barrier pattern 315 and the second magnetic pattern 312 and degradation at an interface between the second magnetic pattern 312 and the first capping pattern 321. As the stress inducing layer 350 is provided, the magnetic properties and electrical properties of the magnetic tunnel junction pattern MTJ may be improved. The magnetic memory device 10 may have improved electrical properties. As the stress inducing layer 350 has a lattice constant less than that of tantalum (Ta), the stress inducing layer 350 may apply sufficient compression stress to the second magnetic pattern 312. For example, as the lattice constant of the stress inducing layer 350 may be 3.3 Å or less, the magnetic tunnel junction pattern MTJ may have further improved perpendicular magnetic anisotropy properties.

The stress inducing layer 350 may have a thickness T1 in a range of about 0.001 nanometers (nm) to about 40 Å. When the stress inducing layer 350 has the thickness T1 exceeding 40 Å, the degradation of the magnetic tunnel junction pattern MTJ may be generated. According to embodiments, as the thickness T1 of the stress inducing layer 350 satisfies the conditions, sufficient stress may be applied to the magnetic tunnel junction pattern MTJ, and thus, the degradation of the magnetic tunnel junction pattern MTJ may be prevented.

The boron trap layer 360 may be disposed on the stress inducing layer 350. The boron trap layer 360 may be disposed between the stress inducing layer 350 and the upper electrode TE. The boron trap layer 360 may be physically in contact with an upper surface of the stress inducing layer 350. The boron trap layer 360 may include a second metal material and boron. In some embodiments, the content (i.e., concentration) of boron in the boron trap layer 360 may be less than the content (i.e., concentration) of the second metal material in the boron trap layer 360. The second metal material in the boron trap layer 360 may include Ta, Mo, Hf, Ti, zirconium (Zr), Co, Fe, and/or an alloy thereof. The second metal material of the boron trap layer 360 may be different from the first metal material of the stress inducing layer 350. When the second metal material is an alloy, the boron trap layer 360 may include, for example, CoFe and/or CoFeB. The boron trap layer 360 may be formed by a deposition process.

In a semiconductor device manufacturing process, the boron in the magnetic tunnel junction pattern MTJ may move toward the stress inducing layer 350. For example, the boron in the second magnetic pattern 312 may move toward the stress inducing layer 350 through the first capping pattern 321 and the second capping pattern 322. Accordingly, the second magnetic pattern 312, the first capping pattern 321, and the second capping pattern 322 may each include boron (B). When the stress inducing layer 350 includes boron exceeding a certain concentration/content, the magnetic tunnel junction pattern MTJ may have high resistance properties or may be degraded. According to embodiments, the boron trap layer 360 may have boron affinity greater than that of the stress inducing layer 350. As the boron trap layer 360 is provided on the upper surface of the stress inducing layer 350, the boron in the stress inducing layer 350 may move toward the boron trap layer 360. Accordingly, the boron trap layer 360 may further include boron in addition to the second metal material. The stress inducing layer 350 may include boron of a certain concentration/content. In other embodiments, the stress inducing layer 350 may not include boron (B). According to embodiments, as the boron trap layer 360 is provided, the magnetic tunnel junction pattern MTJ may have further improved magnetic properties and electrical properties. For example, the magnetic tunnel junction pattern MTJ may have a relatively low resistance by the boron trap layer 360. As the boron trap layer 360 is provided, the perpendicular magnetic anisotropy properties of the magnetic tunnel junction pattern MTJ may satisfy a desired range.

The forming of the boron trap layer 360 may include forming a preliminary boron trap layer (not shown) by a deposition process and patterning the preliminary boron trap layer by an etching process. The boron trap layer 360 may have a thickness T2 in a range of about 0.001 nm to about 40 Å. As the boron trap layer 360 has the thickness T2 of 40 Å or less, a difficulty of a patterning process for forming the boron trap layer 360 may be reduced. In addition, after the etching process for forming the boron trap layer 360, the formation of excessive etching residue may be prevented. As the thickness T2 of the boron trap layer 360 satisfies the condition above, the magnetic memory device 10 may exhibit improved electrical properties.

The upper electrode TE may be disposed on the boron trap layer 360. The upper electrode TE may include a conductive material, such as a metal material or a metal nitride. For example, the upper electrode TE may include Ta, Ru, Ti, TiN, TaN, W, or a combination thereof. The upper electrode TE may be a single layer or a multilayer. The upper electrode TE may be formed by a deposition process.

The upper interlayer insulating layer 120 may be disposed on the lower interlayer insulating layer 110 to be on (e.g., to cover) sidewalls of the information storage structure DS. The upper interlayer insulating layer 120 may include a silicon-containing insulating material. The upper interlayer insulating layer 120 may be a single layer or a multilayer.

The bit line BL may be disposed on the upper interlayer insulating layer 120 and the information storage structure DS. The bit line BL may extend parallel to the first direction D1 from a two-dimensional perspective. The bit line BL may include a conductive material, for example, metal. The bit line BL may be electrically connected to the information storage structure DS. As an example, the bit line BL may be in contact with an upper surface of the upper electrode TE and may be electrically connected to the upper electrode TE. An upper surface of the information storage structure DS may include the upper surface of the upper electrode TE. In another example, a bit line contact plug (not shown) may be provided between the upper electrode TE and the bit line BL, and the bit line BL may be electrically connected to the upper electrode TE through the bit line contact plug.

FIG. 2 is a schematic view for explaining an electrical connection of a semiconductor device according to some embodiments.

Referring to FIG. 2, the semiconductor device according to some embodiments may be the magnetic memory device 10. The magnetic memory device 10 may include the memory cell MC. The memory cell MC may further include a word line WL and a source line SL in addition to the information storage structure DS, the selection element SE, and the bit line BL. The information storage structure DS may include, as described with reference to FIG. 1, the lower electrode BE, the magnetic tunnel junction pattern MTJ, the first capping pattern 321, the second capping pattern 322, the stress inducing layer 350, the boron trap layer 360, and the upper electrode TE.

The selection element SE may include a switching element. The selection element SE may include a field effect transistor. The information storage structure DS may be connected to a first source/drain of the selection element SE. For example, the magnetic tunnel junction pattern MTJ may be electrically connected to the first source/drain of the selection element SE through the lower electrode BE. The source line SL may be connected to a second source/drain of the selection element SE. Accordingly, the magnetic tunnel junction pattern MTJ may be connected to the source line SL through the lower electrode BE and the selection element SE. The word line WL may be connected to a gate of the selection element SE. The magnetic tunnel junction pattern MTJ may be electrically connected to the bit line BL through the upper electrode TE. Unlike the illustration, in other embodiments, the magnetic tunnel junction MTJ pattern may be connected to the bit line BL through the lower electrode BE and the selection element SE, and to the source line SL through the upper electrode TE.

According to some embodiments, the magnetic tunnel junction pattern MTJ may be selectively connected to the source line SL by turning the selection element SE on/off through the control of a voltage of the word line WL. For a write operation of the magnetic memory device 10, the selection element SE may be turned on by applying a voltage to the word line WL, and a write current may be applied between the bit line BL and the source line SL. In this state, the magnetization direction of the second magnetic pattern 312 may be determined depending on the direction of a write current.

For a read operation of the magnetic memory device 10, the selection element SE may be turned on by applying a voltage to the word line WL, and data stored in the magnetic tunnel junction pattern MTJ may be identified by applying a read current between the bit line BL and the source line SL. In this state, as the read current is very small compared with the write current, the magnetization direction of the second magnetic pattern 312 may not be changed by the read current.

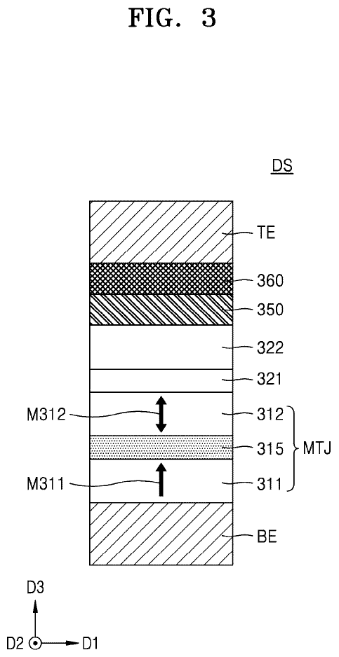

FIG. 3 is a schematic view for explaining the magnetic tunnel junction pattern MTJ of the information storage structure DS according to some embodiments.

Referring to FIG. 3, the information storage structure DS may include the lower electrode BE, the magnetic tunnel junction pattern MTJ, the first capping pattern 321, the second capping pattern 322, the stress inducing layer 350, the boron trap layer 360, and the upper electrode TE. The magnetic tunnel junction pattern MTJ may include the first magnetic pattern 311, the tunnel barrier pattern 315, and the second magnetic pattern 312.

The first magnetic pattern 311 may be a pinned layer. The first magnetic pattern 311 may have a first magnetization direction M311 that is fixed in one direction. The second magnetic pattern 312 may have a second magnetization direction M312 that is changeable to be parallel to or antiparallel to the first magnetization direction M311 that is fixed. In this state, the first and second magnetization directions M311 and M312 of the first and second magnetic patterns 311 and 312 may be substantially perpendicular to a surface of the tunnel barrier pattern 315 contacting the second magnetic pattern 312. For example, the first and second magnetization directions M311 and M312 of the first and second magnetic patterns 311 and 312 may be parallel to or antiparallel to the third direction D3.

The first magnetic pattern 311 may be thicker than the second magnetic pattern 312 (e.g., in the third direction D3), and the coercive force of the first magnetic pattern 311 may be greater than the coercive force of the second magnetic pattern 312. The tunnel barrier pattern 315 may be substantially the same as the example described with reference to FIG. 1.

As illustrated, the first magnetic pattern 311, the tunnel barrier pattern 315, and the second magnetic pattern 312 may be sequentially stacked above the lower electrode BE, and the upper electrode TE may be disposed on the second magnetic pattern 312. In other embodiments, the second magnetic pattern 312, the tunnel barrier pattern 315, and the first magnetic pattern 311 may be sequentially stacked above the lower electrode BE, and the upper electrode TE may be disposed on the first magnetic pattern 311.

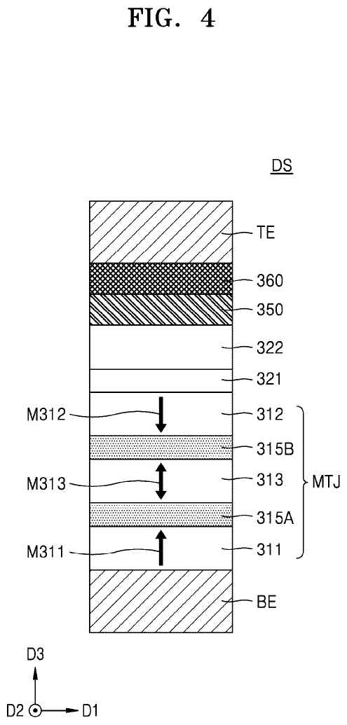

FIG. 4 is a schematic view for explaining the magnetic tunnel junction pattern MTJ of the information storage structure DS according to further embodiments.

Referring to FIG. 4, the information storage structure DS may include the lower electrode BE, the magnetic tunnel junction pattern MTJ, the first capping pattern 321, the second capping pattern 322, the stress inducing layer 350, the boron trap layer 360, and the upper electrode TE. The magnetic tunnel junction pattern MTJ may further include a third magnetic pattern 313 in addition to the first magnetic pattern 311 and the second magnetic pattern 312. The magnetic tunnel junction pattern MTJ may include a tunnel barrier pattern. The tunnel barrier pattern may include a first tunnel barrier pattern 315A and a second tunnel barrier pattern 315B.

The first magnetic pattern 311 may be substantially the same as the example described with reference to FIGS. 1 to 3. The third magnetic pattern 313 may be provided between the first magnetic pattern 311 and the second magnetic pattern 312. The third magnetic pattern 313 may include a ferromagnetic material. The third magnetic pattern 313 may further include boron (B), but the present disclosure is not limited thereto. For example, the third magnetic pattern 313 may include CoFe, CoB, CoFeB, CoNi, CoCr, CoPt, FeB, CeFeAl, or a combination thereof. The first magnetic pattern 311 may have a crystalline structure. The third magnetic pattern 313 may be a single layer or a multilayer. The first magnetization direction M311 of the first magnetic pattern 311, the second magnetization direction M312 of the second magnetic pattern 312, and a third magnetization direction M313 of the third magnetic pattern 313 may be parallel to or antiparallel to the third direction D3. The first magnetic pattern 311 and the second magnetic pattern 312 may each function as a pinned layer. The first magnetization direction M311 and the second magnetization direction M312 may be fixed in a direction parallel to or antiparallel to the third direction D3. The third magnetic pattern 313 may be a free layer. The third magnetization direction M313 may be changed to be parallel to or antiparallel to the first magnetization direction M311.

When the first magnetization direction M311 of the first magnetic pattern 311 is fixed in a direction opposite to the third magnetization direction M313 of the third magnetic pattern 313, the first magnetization direction M311 of the first magnetic pattern 311 may be substantially offset by the third magnetization direction M313 of the third magnetic pattern 313. Accordingly, the magnetic tunnel junction pattern MTJ according to embodiments may perform a read operation by using a relatively small current.

The first tunnel barrier pattern 315A may be provided between the first magnetic pattern 311 and the third magnetic pattern 313. The second tunnel barrier pattern 315B may be provided between the third magnetic pattern 313 and the second magnetic pattern 312. The first tunnel barrier pattern 315A and the second tunnel barrier pattern 315B may each include the material described in the example of the tunnel barrier pattern 315 described with reference to FIG. 1. The second tunnel barrier pattern 315B may include a material that is the same as or different from the material of the first tunnel barrier pattern 315A. As the magnetic tunnel junction pattern MTJ according to embodiments provides a relatively high resistance in the read operation due to the second tunnel barrier pattern 315B, a clear resistance value may be obtained.

The number of magnetic patterns 311, 312, and 313 and the number of tunnel barrier patterns 315A and 315B included in the magnetic tunnel junction pattern MTJ may be variously changed. For example, although not illustrated, the magnetic tunnel junction pattern MTJ may further include a fourth magnetic pattern and a third tunnel barrier pattern.

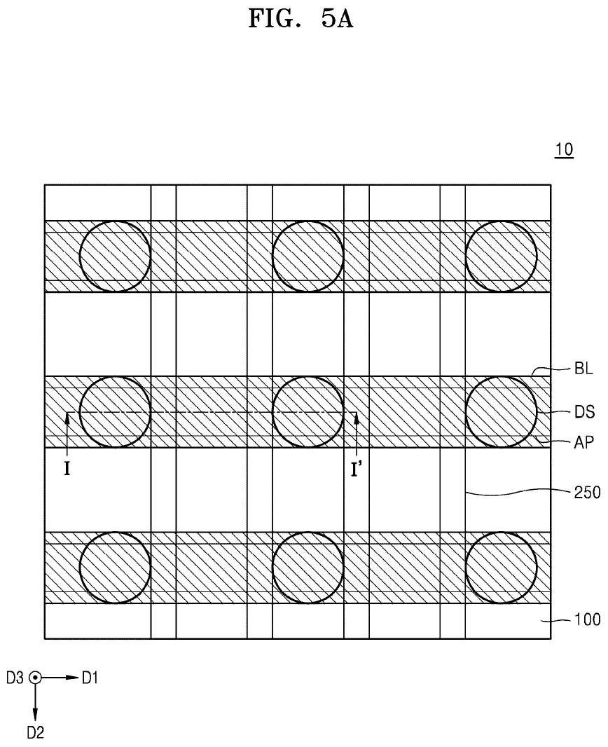

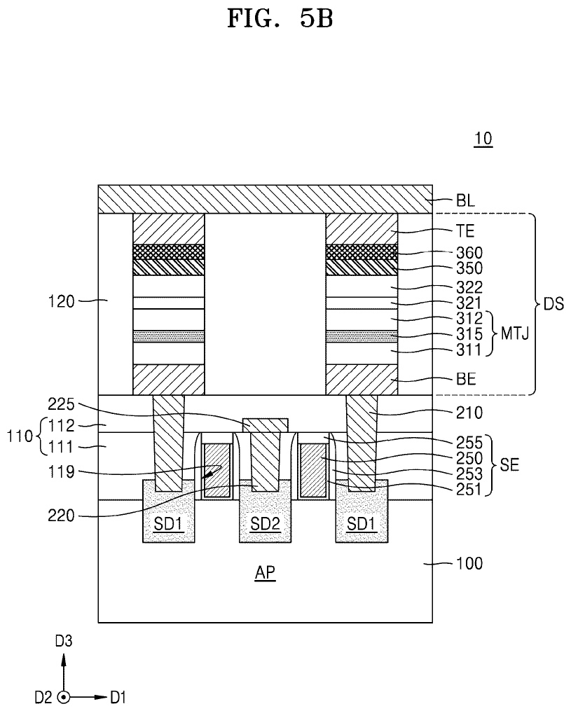

FIG. 5A is a plan view of a semiconductor device according to some embodiments. FIG. 5B is a cross-sectional view of the semiconductor device taken along a line I-I′ of FIG. 5A.

Referring to FIGS. 5A and 5B, the semiconductor device according to some embodiments may be the magnetic memory device 10. The magnetic memory device 10 may include the substrate 100, the selection element SE, the lower interlayer insulating layer 110, the conductive plug 210, the information storage structure DS, the upper interlayer insulating layer 120, and the bit line BL.

The substrate 100 may be substantially the same as that described with reference to FIG. 1. For example, the substrate 100 may be a semiconductor substrate. The substrate 100 may include an active pattern AP. The active pattern AP may protrude from the upper surface of the substrate 100. The active pattern AP may extend parallel to the first direction D1 from a two-dimensional perspective. The active pattern AP may be formed of a semiconductor material. As an example, the active pattern AP may correspond to a portion of the substrate 100 (e.g., an upper portion of the substrate 100). In other words, the active pattern AP may be connected to the substrate 100 without a boundary surface. In another example, the active pattern AP may include an epitaxial layer grown from the substrate 100. The active pattern AP may further include dopants.

The selection element SE may be disposed on the substrate 100. The selection element SE may be a fin field effect transistor (FinFET), and the type of the selection element SE is not limited to the illustration and may be variously changed. The selection element SE may include a first source/drain pattern SD1, a second source drain pattern SD2, and a gate pattern 250.

The lower interlayer insulating layer 110 may be provided on the substrate 100. The lower interlayer insulating layer 110 may include a first lower interlayer insulating layer 111 and a second lower interlayer insulating layer 112. The first lower interlayer insulating layer 111 may be provided on the substrate 100 and may have an opening 119. The opening 119 may penetrate (i.e., extend in) the first lower interlayer insulating layer 111 to expose the active pattern AP. The first lower interlayer insulating layer 111 and the second lower interlayer insulating layer 112 may each include a silicon-based insulating material. The first lower interlayer insulating layer 111 may be a single layer or a multilayer.

The gate pattern 250 may extend across the active pattern AP on the substrate 100 and the active pattern AP. For example, the gate pattern 250 may extend in the second direction D2 from a two-dimensional perspective. Although not illustrated, the gate pattern 250 may be provided on an upper surface and a sidewall of the active pattern AP. The gate pattern 250 may be provided within the opening 119 of the first lower interlayer insulating layer 111. The gate pattern 250 may be formed by a replacement gate process. The gate pattern 250 may include the gate electrode of the selection element SE, and may further include at least a part of the word line WL described with reference to FIG. 2. The gate pattern 250 may include, for example, at least one of doped semiconductor, conductive metal nitride, metal silicide, or metal.

The selection element SE may further include a gate capping pattern 255. The gate capping pattern 255 may be provided on top of the gate pattern 250 to be on (e.g., to cover) an upper surface of the gate pattern 250. The gate capping pattern 255 may include silicon oxide, silicon nitride, silicon oxynitride, a low-dielectric material, or a combination thereof.

A gate insulating pattern 251 may be provided within the opening 119 of the first lower interlayer insulating layer 111, and may be disposed between the gate pattern 250 and the active pattern AP and between the gate pattern 250 and the first lower interlayer insulating layer 111. The gate insulating pattern 251 may be on (e.g., may cover) the lower surface and sidewall of the gate pattern 250. The gate insulating pattern 251 may have a U-shaped cross-section. The gate insulating pattern 251 may include a silicon-containing insulating material and a high-k dielectric material.

The selection element SE may further include spacer patterns 253. The spacer patterns 253 may be provided on both (i.e., opposite) sidewalls of the gate pattern 250 to be on (e.g., to cover) the gate insulating pattern 251. The opening 119 of the first lower interlayer insulating layer 111 may expose inner walls of the spacer patterns 253. The spacer patterns 253 may include a silicon oxide film, a silicon nitride film, and/or a silicon carbonitride film.

The first source/drain pattern SD1 may be provided on the active pattern AP on one side of the gate pattern 250. A second source/drain pattern SD2 may be provided on the active pattern AP on the other side of the gate pattern 250. The other side of the gate pattern 250 may face the one side thereof (e.g., in the first direction D1). The active pattern AP may have recess portions. The first and second source/drain patterns SD1 and SD2 may be provided within the recess portions. The portion of the active pattern AP between the first and second source/drain patterns SD1 and SD2 may function as a channel region of the selection element SE. The first source/drain pattern SD1 may correspond to the first source/drain of the selection element SE described with reference to FIG. 2. The second source/drain pattern SD2 may correspond to the second source/drain of the selection element SE described with reference to FIG. 2. Lower surfaces of the first and second source/drain patterns SD1 and SD2 may be located at a level lower than the top surface of the active pattern AP. In other words, lower surfaces of the first and second source/drain patterns SD1 and SD2 may be lower in the third direction D3 than the top surface of the active pattern AP (e.g., when measured relative to a lower surface of the substrate 100). Upper surfaces of the first and second source/drain patterns SD1 and SD2 may be located at a level higher than the top surface of the active pattern AP. In other words, upper surfaces of the first and second source/drain patterns SD1 and SD2 may be higher in the third direction D3 than the top surface of the active pattern AP (e.g., when measured relative to the lower surface of the substrate 100). In the present disclosure, a level of a certain component may refer to a vertical level measured in a vertical direction (e.g., in the third direction D3). A level difference between two components may be measured in a direction parallel to the third direction D3. The first and second source/drain patterns SD1 and SD2 may be epitaxial patterns. The epitaxial patterns may refer to patterns formed by an epitaxial growth process. The first and second source/drain patterns SD1 and SD2 may each include a semiconductor material, for example, silicon, germanium, silicon-germanium (SiGe), and/or silicon carbide (SiC).

The magnetic memory device 10 may further include a lower plug 220 and a conductive pattern 225. The lower plug 220 may be provided in the first lower interlayer insulating layer 111 to be electrically connected to the second source/drain pattern SD2. The lower plug 220 may include metal, metal nitride, metal silicide, and/or a combination thereof. The conductive pattern 225 may be disposed on the lower plug 220 to be in contact with the lower plug 220. The conductive pattern 225 may include, for example, metal.

The second lower interlayer insulating layer 112 may be disposed on the first lower interlayer insulating layer 111. The second lower interlayer insulating layer 112 may be on (e.g., may cover) the conductive pattern 225. The second lower interlayer insulating layer 112 may be a single layer or a multilayer.

The conductive plug 210 may be provided in the lower interlayer insulating layer 110. For example, the conductive plug 210 may penetrate the first and second lower interlayer insulating layers 111 and 112. The conductive plug 210 may be provided on the first source/drain pattern SD1 to be electrically connected to the first source/drain pattern SD1. The conductive plug 210 may be spaced apart from the lower plug 220 to be electrically separated (i.e., electrically isolated) therefrom. The conductive plug 210 may include metal, metal nitride, metal silicide, and/or a combination thereof.

The information storage structure DS may be disposed on the conductive plug 210 to be electrically connected to the first source/drain pattern SD1 through the conductive plug 210. The information storage structure DS may further extend above a portion of an upper surface of the second lower interlayer insulating layer 112. The information storage structure DS may include, as described with reference to FIGS. 1 to 4, the lower electrode BE, the magnetic tunnel junction pattern MTJ, the first capping pattern 321, the second capping pattern 322, the stress inducing layer 350, the boron trap layer 360, and the upper electrode TE.

The information storage structure DS may be any one of a plurality of information storage structures DS. The information storage structures DS may be arranged two-dimensionally in the first direction D1 and the second direction D2, as illustrated in FIG. 5A.

The upper interlayer insulating layer 120 may be disposed on an upper surface of the lower interlayer insulating layer 110. The upper interlayer insulating layer 120 may be on (e.g., may cover) sidewalls of the information storage structures DS. The upper interlayer insulating layer 120 may be a multilayer, but the present disclosure is not limited thereto.

The bit line BL may be disposed on the information storage structures DS to be electrically connected to the information storage structures DS. The bit line BL may extend over an upper surface of the upper interlayer insulating layer 120. As illustrated in FIG. 5A, the bit line BL may extend parallel to the first direction D1 from a two-dimensional perspective. The bit line BL may be any one of a plurality of bit lines BL. The bit lines BL may be spaced apart from each other in the second direction D2.

Hereinafter, referring to Comparative Examples and Experimental Example, manufacturing of an information storage structure DS and properties evaluation results are described according to some embodiments.

### —Manufacturing of Information Storage Structure—

### Comparative Example 1

A lower electrode BE may be formed on a substrate 100. A magnetic tunnel junction pattern MTJ may be formed by sequentially depositing a CoFeB layer, a magnesium oxide (MgO) layer, and a CoFeB layer on the lower electrode BE. A first capping pattern 321 may be formed by depositing a Ta layer on the magnetic tunnel junction pattern MTJ, and a second capping pattern 322 may be formed by depositing a Ru layer thereon. A third capping pattern (not shown) may be formed by depositing a Ta layer on the second capping pattern 322. An upper electrode TE may be formed by depositing a Ru layer on the third capping pattern.

### Comparative Example 2

An information storage element is manufactured by the same method as Comparative Example 1. However, a stress inducing layer 350 may be formed by depositing a Mo layer on a second capping pattern 322 instead of a third capping pattern. An upper electrode TE may be formed on the Mo layer.

### Experimental Example

An information storage element is manufactured by the same method as Comparative Example 1. However, a stress inducing layer 350 may be formed by depositing a Mo layer on a second capping pattern 322 instead of a third capping pattern. A boron trap layer 360 may be formed by depositing a Ta layer on the Mo layer. An upper electrode TE may be formed on the Ta layer.

### —Evaluation of Information Storage Structure—

Table 1 shows properties evaluation results of Comparative Example 1, Comparative Example 2, and Experimental Example. In this state, the dispersion of an anisotropic magnetic field is obtained by calculating the dispersion of anisotropic magnetic fields between a plurality of information storage elements manufactured from a single wafer.

TABLE 1

| | Comparative | Comparative | Experimental |
|---|---|---|---|
| | Example 1 | Example 2 | Example |
| Anisotropic Magnetic | 6531 | 9499 | 7418 |
| Field (Oe) | | | |
| Dispersion of Anisotropic | 1175 | 1816 | 1033 |
| Magnetic Field (Oe) | | | |
| Resistance Area (Ω/μm²) | 13.84 | 19.95 | 15.04 |

Referring to Table 1, Comparative Example 1 does not include the stress inducing layer 350. Comparative Example 2 and Experimental Example each include the stress inducing layer 350 and show anisotropic magnetic field properties greater than those of Comparative Example 1. Interfacial perpendicular magnetic anisotropy properties may be evaluated by an anisotropic magnetic field. According to some embodiments, the information storage structure DS may include the stress inducing layer 350 and may exhibit improved interfacial perpendicular magnetic anisotropy properties.

Comparative Example 2 does not include a boron trap layer 360 and exhibits a dispersion of a relatively large anisotropic magnetic field. Experimental Example includes a boron trap layer 360 and exhibits a dispersion of a relatively small anisotropic magnetic field. The information storage structure DS of Experimental Example includes a boron trap layer 360 and exhibits uniform perpendicular magnetic anisotropy properties.

While Comparative Example 2 has a high resistance area, Comparative Example 1 and Experimental Example have a relatively low resistance area. The resistance areas of Comparative Example 1 and Experimental Example satisfy film resistivity requirements. The information storage structure DS of Experimental Example includes a boron trap layer 360, and thus, a resistance increase effect due to the stress inducing layer 350 may be restricted. The information storage structure DS of Experimental Example may exhibit good electrical properties.

According to the inventive concepts, the information storage structure may include the stress inducing layer, have improved interfacial perpendicular magnetic anisotropy properties, and prevent degradation of the magnetic tunnel junction pattern. The information storage structure may include the boron trap layer and exhibit uniform perpendicular magnetic anisotropy properties and low resistance properties. Accordingly, the magnetic properties and electrical properties of the magnetic tunnel junction pattern may be improved. The magnetic memory device may exhibit improved magnetic properties and electrical properties.

While the inventive concepts have been particularly shown and described with reference to example embodiments thereof, it will be understood that various changes in form and details may be made therein without departing from the scope of the following claims.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. As used herein, the term “and/or” includes any and all combinations of one or more of the associated listed items.

It will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

What is claimed is:

1. A magnetic memory device comprising:
a lower electrode on a substrate;
a magnetic tunnel junction pattern on the lower electrode, the magnetic tunnel junction pattern comprising a first magnetic pattern, a tunnel barrier pattern, and a second magnetic pattern;
an upper electrode on the magnetic tunnel junction pattern;
a capping pattern between the magnetic tunnel junction pattern and the upper electrode;
a stress inducing layer between the capping pattern and the upper electrode; and
a boron trap layer between the stress inducing layer and the upper electrode, the boron trap layer comprising boron,
wherein each of the stress inducing layer and the second magnetic pattern comprises boron.

2. The magnetic memory device of claim 1, wherein the capping pattern comprises boron.

3. The magnetic memory device of claim 1, wherein the capping pattern comprises:
a first capping pattern; and
a second capping pattern between the first capping pattern and the stress inducing layer, the second capping pattern comprising a metal different from a metal included in the first capping pattern and a metal included in the stress inducing layer.

4. The magnetic memory device of claim 3, wherein each of the first capping pattern and the second capping pattern comprises boron.

5. The magnetic memory device of claim 1, wherein the stress inducing layer comprises a first metal,
wherein the boron trap layer comprises a second metal different from the first metal,
wherein a content of boron in the stress inducing layer is less than a content of the first metal in the stress inducing layer, and
wherein a content of boron in the boron trap layer is less than a content of the second metal in the boron trap layer.

6. The magnetic memory device of claim 1, wherein the boron trap layer is in contact with the stress inducing layer.

7. A magnetic memory device comprising:
a lower electrode on a substrate;
a magnetic tunnel junction pattern on the lower electrode;
a capping pattern on the magnetic tunnel junction pattern;
a stress inducing layer on the capping pattern and having a lattice constant less than a lattice constant of tantalum;
a boron trap layer in contact with the stress inducing layer; and
an upper electrode on the boron trap layer.

8. The magnetic memory device of claim 7, wherein the lattice constant of the stress inducing layer is 3.3 Å or less.

9. The magnetic memory device of claim 7, wherein the capping pattern comprises a first capping pattern, and
wherein the first capping pattern comprises tantalum, tantalum oxide, tantalum nitride, aluminum nitride, zirconium nitride, and/or niobium nitride.

10. The magnetic memory device of claim 9, wherein the capping pattern further comprises a second capping pattern between the first capping pattern and the stress inducing layer, and
wherein the second capping pattern comprises a metal different from a metal included in the first capping pattern and a metal included in the stress inducing layer.

11. The magnetic memory device of claim 10, wherein the second capping pattern comprises ruthenium, ruthenium oxide, and/or a ruthenium alloy.

12. The magnetic memory device of claim 7, wherein the stress inducing layer comprises molybdenum, tungsten, hafnium, and/or an alloy thereof,
wherein the boron trap layer comprises tantalum, molybdenum, hafnium, titanium, zirconium, cobalt iron, cobalt iron boride, and/or an alloy thereof, and
wherein the boron trap layer comprises a metal different from a metal included in the stress inducing layer.

13. The magnetic memory device of claim 7, wherein the boron trap layer is between the stress inducing layer and the upper electrode.

14. The magnetic memory device of claim 7, wherein the magnetic tunnel junction pattern comprises a first magnetic pattern, a tunnel barrier pattern, and a second magnetic pattern that are stacked,
wherein the second magnetic pattern is between the tunnel barrier pattern and the capping pattern,
wherein the second magnetic pattern comprises boron, and
wherein the boron trap layer comprises boron.

15. The magnetic memory device of claim 14, wherein the stress inducing layer comprises boron.

16. The magnetic memory device of claim 7, wherein the stress inducing layer has a thickness in a range of about 0.001 nm to about 40 Å, and
wherein the boron trap layer has a thickness in a range of about 0.001 nm to about 40 Å.

17. A semiconductor device comprising:
a semiconductor substrate;
a selection element on the semiconductor substrate;
a lower interlayer insulating layer on the semiconductor substrate and the selection element;
a conductive plug in the lower interlayer insulating layer and electrically connected to the selection element;
an information storage structure on the conductive plug; and
a bit line on the information storage structure,
wherein the information storage structure comprises:
a lower electrode electrically connected to the conductive plug;
a magnetic tunnel junction pattern on the lower electrode, the magnetic tunnel junction pattern comprising a first magnetic pattern, a tunnel barrier pattern, and a second magnetic pattern;
a first capping pattern on an upper surface of the second magnetic pattern, the first capping pattern comprising a metal different from a metal included in the second magnetic pattern;
a second capping pattern on the upper surface of the second magnetic pattern, the second capping pattern comprising a metal different from the metal included in the second magnetic pattern and the metal included in the first capping pattern;
a stress inducing layer on an upper surface of the second capping pattern, the stress inducing layer having a lattice constant lower than a lattice constant of tantalum;
a boron trap layer between the stress inducing layer and the bit line; and
an upper electrode between the boron trap layer and the bit line.

18. The semiconductor device of claim 17, wherein the semiconductor substrate comprises an active pattern protruding from an upper surface of the semiconductor substrate,
wherein the selection element comprises:
a gate pattern extending across the active pattern on the semiconductor substrate; and
source/drain patterns on opposite sides of the gate pattern, respectively, and
wherein upper surfaces of the source/drain patterns are higher in a vertical direction than a top surface of the active pattern, relative to a lower surface of the semiconductor substrate.

19. The semiconductor device of claim 17, wherein the second magnetic pattern comprises a ferromagnetic material and boron,
wherein the stress inducing layer comprises a first metal and boron,
wherein the boron trap layer comprises a second metal and boron, and
wherein the second metal is different from the first metal.

20. The semiconductor device of claim 19, wherein the first capping pattern comprises tantalum, tantalum oxide, tantalum nitride, aluminum nitride, zirconium nitride, and/or niobium nitride,
wherein the second capping pattern comprises ruthenium, tantalum, titanium, titanium nitride, tantalum nitride, tungsten, and/or a combination thereof,
wherein the first metal comprises molybdenum, tungsten, hafnium, and/or an alloy thereof, and
wherein the second metal comprises tantalum, molybdenum, hafnium, titanium, zirconium, cobalt, iron, and/or an alloy thereof.
